(19) United States
(12) Patent Application Publication
(10) Pub. No.: US 2005/0266640 A1
(43) Pub. Date: Dec. 1, 2005

(54) Method of forming a dielectric layer and method of manufacturing a nonvolatile memory device using the same

(76) Inventors: Young-Sub You, Gyeonggi-do (KR); Woong Lee, Seoul (KR); Hun-Hyeoung Leam, Gyeonggi-do (KR); Hyeon-Deok Lee, Seoul (KR); Ki-Su Na, Gyeonggi-do (KR); Yong-Woo Hyung, Gyeonggi-do (KR); Jai-Dong Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/124,517

(22) Filed: May 6, 2005

(30) Foreign Application Priority Data
May 31, 2004 (KR) 2004-38901

(51) Int. Cl. H01L 21/336; H01L 21/4763

(52) U.S. Cl. 438/261; 438/257; 438/591; 438/593

(57) ABSTRACT

A method of forming a dielectric layer having a reduced thickness according to embodiments of the invention includes forming a lower oxide layer on a substrate, and forming a nitride layer on the lower oxide layer. Then, a preliminary oxide layer is formed on the nitride layer. A radical oxidation process using oxygen radicals is performed on the preliminary oxide layer to form an upper oxide layer on the nitride layer. The dielectric layer includes an ONO composite layer consisting of the lower oxide layer, the nitride layer, and the upper oxide layer. Due to the decreased thickness of the dielectric layer, the dielectric layer has an improved capacitance and an increased coupling coefficient.

### CROSS-REFERENCE TO RELATED APPLICATIONS

This application claims priority from Korean Patent Application No. 2004-38901 filed on May 31, 2004, the content of which is herein incorporated by reference in its entirety.

### BACKGROUND OF THE INVENTION

1. Field of the Invention

This disclosure generally relates to a method of forming a dielectric layer and a method of manufacturing a nonvolatile memory device using the same dielectric layer. More particularly, this disclosure relates to a method of forming a dielectric layer comprising an oxide/nitride/oxide (ONO) composite layer and a method of manufacturing a nonvolatile memory device using the same.

2. Description of the Related Art

In general, a semiconductor memory device is classified as either a volatile memory device or a nonvolatile memory device depending on whether the data stored in the memory device is erased when power to the device is turned off. Data stored in volatile memory devices such as Dynamic Random Access Memory (DRAM) and Static Random Access Memory (SRAM) are erased when the power is turned off, and data stored in nonvolatile memory device are not erased but maintained over time even though the power is turned off.

Nonvolatile memory devices may include a mask Read-Only Memory (ROM) that has been programmed by a manufacturer, an Erasable-Programmable ROM (EPROM), an Electrically Erasable-Programmable ROM (EEPROM), and a Flash Erasable-Programmable ROM (FEPROM). The data in the mask ROM are not erasable and programmable, and other nonvolatile memory devices are erasable and reusable memory cells that are often used in digital cellular phones, digital cameras, LAN switches, etc. Recently, one modification of the conventional EEPROM, known in particular as a flash memory device, has become widespread as digital conveniences have proliferated.

A flash memory cell typically includes a transistor, a floating gate, and a control gate disposed above the floating gate in a stacked gate structure. The floating gate is electrically isolated from the underlying semiconductor substrate by a thin dielectric layer formed on the substrate. Since charges are transferred across the dielectric layer by quantum-mechanical tunneling, the dielectric layer is often referred to as a tunnel oxide layer. The control gate is disposed above the floating gate and separated from it by a storage dielectric layer such as an oxide/nitride/oxide (ONO) layer.

Both the programming and erasing of a memory cell in the flash memory device takes place through charge transfer processes to/from the floating gate across the tunnel oxide layer by a voltage applied between the control gate and the substrate. The storage dielectric layer maintains the state of charge stored in the floating gate, and applies the control gate voltage to the floating gate.

FIG. 1 is a sectional diagram illustrating a conventional nonvolatile memory device.

Referring to FIG. 1, the conventional nonvolatile memory device includes a floating gate 14 and a control gate 24 sequentially stacked on a substrate 10 through mediums of dielectric layers. A tunnel oxide layer 12, which is a kind of an insulation layer such as the dielectric layer, is first formed on the substrate 12 on which a shallow trench isolation structure (not shown) is formed, and then the floating gate 14 is formed on the tunnel oxide layer. A storage dielectric layer 22 such as the ONO layer is formed on the floating gate 14, and the control gate 24 is formed on the storage dielectric layer 22.

Applying a positive voltage to the control gate 24 and the substrate 10 forces electrons to reach the floating gate 14, so that the floating gate 14 is programmed by collecting and storing the electrons to thereby represent an electrically “on” state. In contrast, applying a negative voltage to the control gate 24 and applying a positive voltage to the substrate 10 force electrons to move from the floating gate 14 through the tunnel oxide layer 12, and the electrons are accelerated into the substrate 10, for example, a source on the substrate 10, so that the floating gate 14 is erased to represent an electrically “off” state. The storage dielectric layer 22 maintains the state of charge stored in the floating gate 14, and ensures that the control gate voltage is also applied to the floating gate.

Here, the floating gate voltage induced from the control gate voltage is proportionally determined by a coupling coefficient between the floating gate 14 and the control gate 24. The coupling coefficient R is represented as the following equation (1):
R═C_{ONO}/(C_{ONO}+C_{TO}) (1)

In the equation (1), C_{ONO} represents a capacitance of the storage dielectric layer 22, and C_{TO} represents a capacitance of a gate oxide layer in a transistor.

Because the coupling coefficient R is proportional to the capacitance C_{ONO} of the storage dielectric layer 22, the floating gate voltage is also proportional to the capacitance C_{ONO} of the storage dielectric layer 22.

Meanwhile, a capacitance C of a capacitor is generally determined as the following equation (2):
C=εA/T (2)

In the equation (2), ε represents a dielectric constant of the capacitor, and A and T indicate a surface area and a thickness of the capacitor, respectively. According to the equation (2), the capacitance of a capacitor is proportional to the surface area A and inversely proportional to the thickness T thereof.

Accordingly, a high coupling coefficient R requires a large surface area or a small thickness of the dielectric constant. However, it is difficult to form a thin oxide layer on the floating gate 14, which is typically polysilicon, and as a result, the storage dielectric layer 22 is typically an ONO composite layer that includes a first oxide layer 16, a nitride layer 18 disposed on the first oxide layer, and a second oxide layer 20 disposed on the nitride layer.

The first oxide layer 16 is formed on the floating gate 14 with a thermal oxidation process, and then the nitride layer 18 is formed on the first oxide layer 16 with a low-pressure chemical vapor deposition (LPCVD) process. The second oxide layer 20 is also formed on the nitride layer 18 with a thermal oxidation process.

The structure of the nitride layer 18 is less compact than that of an oxide layer, such that small and minute holes, referred to as pinholes, may be formed on a surface thereof. The second oxide layer 20 is formed for preventing process failures caused by the pinholes of the nitride layer 18. Accordingly, the second oxide layer 20 determines the dielectric characteristics of the ONO layer. Conventionally, a wet thermal oxidation process is utilized to form the second oxide layer 20. According to the wet thermal oxidation process, an oxide layer is formed to a thickness of about 1500 Å to about 2000 Å on a silicon substrate. However, the oxide layer is at most formed to a thickness of about 10 Å to about 20 Å on a nitride layer.

Accordingly, forming the second oxide layer 20 to a thickness over about 70 Å using the conventional wet thermal oxidation process requires a high temperature of no less than about 950° C. However, the high temperature of the wet thermal oxidation process causes a thermal stress between the storage dielectric layer 12 and the floating gate 14, and as a result, the storage dielectric layer 12, for example an oxide layer, may thermally deteriorate due to the thermal stress. The second oxide layer 20 may be formed to a thickness of that is below about 70 Å in order to reduce the effect of the thermal stress, but the drawback is that the leakage current is greatly increased due to the small thickness of the second oxide layer 20.

When an oxide layer is formed on a polysilicon layer, the thickness of the oxide layer is generally increased in proportion to a concentration of impurities in the polysilicon layer due to oxidation enhancement. Therefore, it is difficult to form the first oxide layer 16 on the floating gate 14 to a sufficiently small thickness since the floating gate 14 includes polysilicon.

Various methods have been researched to overcome the above-mentioned shortcomings of an oxide layer. For example, U.S. Pat. No. 5,591,681 to Wristers, et al. (“Wristers”) discloses a method of forming a surface layer on an oxide layer containing a concentration of nitrogen. According to Wristers, an oxide layer is formed using a process that includes annealing a semiconductor substrate in an ambient of about 5% nitrogen monoxide (NO) gas after the oxide layer has been formed. However, the above oxide layer is disadvantageous in that a plurality of nitrogen (N) is positioned inside the oxide layer as well as on a surface of the oxide layer, so that the leakage current is increased through the oxide layer.

Furthermore, U.S. Pat. No. 5,836,772 to Chang, et al. (“Chang”) discloses a method of forming first and second oxide layers using a wet thermal oxidation process in an ambient of an oxygen (O₂) gas or a dinitrogen monoxide (N₂O) gas. However, the oxide layer disclosed by Chang is disadvantageous in that it is difficult to form the first oxide layer to a thickness of about 70 Å, so that the dielectric layer has its own limit in reducing the thickness thereof.

Embodiments of the invention address these and other disadvantages of the conventional art.

### SUMMARY OF THE INVENTION

Embodiments of the invention include a method of forming a dielectric layer that includes an oxide layer with a compact structure and increased capacitance. Accordingly, a coupling coefficient of the dielectric layer is increased since the dielectric layer is formed to have a smaller thickness to thereby improve an insulation characteristic of the dielectric layer. Furthermore, the leakage of electrons stored in the floating gate electrode is prevented, so that a leakage current may be decreased in the nonvolatile memory cell.

### BRIEF DESCRIPTION OF THE DRAWINGS

The above and other features and advantages of the invention will become readily apparent by reference to the following detailed description when considering in conjunction with the accompanying drawings.

FIG. 1 is a sectional diagram illustrating a conventional nonvolatile memory device.

FIGS. 2 to 5 are sectional diagrams illustrating some exemplary processes for a method of forming a dielectric layer having an ONO composite structure according to some embodiments of the invention.

FIGS. 6 to 8 are sectional diagrams illustrating some exemplary processes for a method of forming a dielectric layer having an ONO composite structure according to some other embodiments of the invention.

FIGS. 9 to 17 are sectional diagrams illustrating some exemplary processes for a method of manufacturing a nonvolatile memory device having a dielectric layer with an ONO composite structure according to still other embodiments of the invention.

FIGS. 18 to 23 are sectional diagrams illustrating some exemplary processes for a method of manufacturing a nonvolatile memory device having a dielectric layer with an ONO composite structure according to different embodiments of the invention.

### DESCRIPTION OF THE EMBODIMENTS

The invention is described more fully below with reference to the accompanying drawings in which exemplary embodiments of the invention are shown.

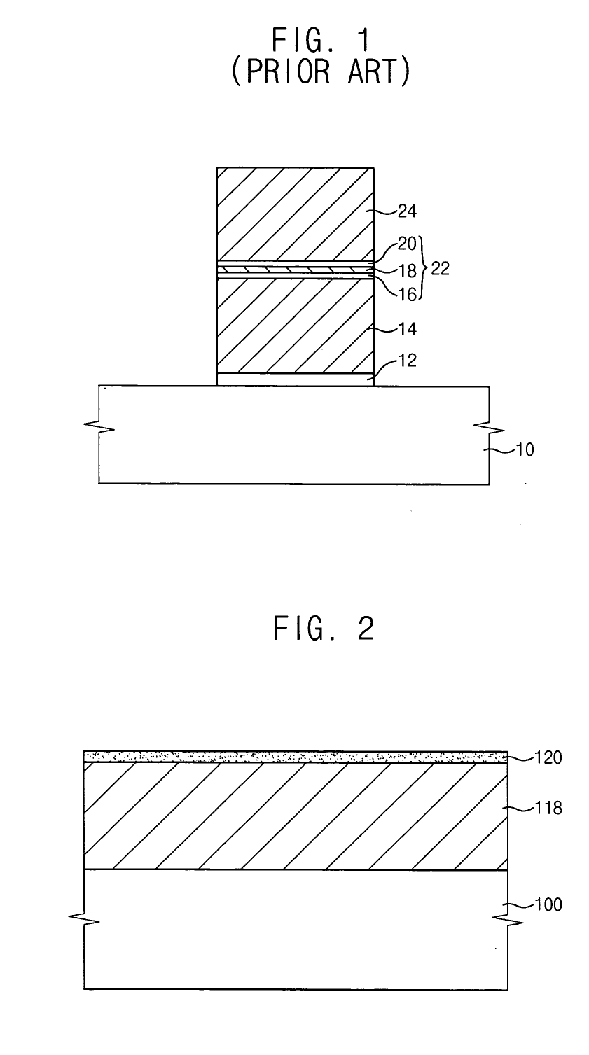

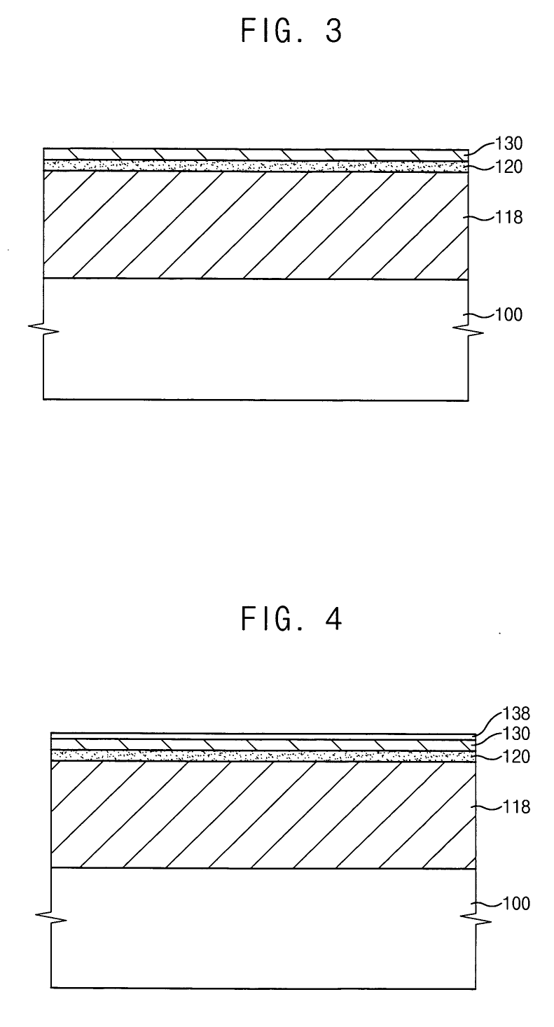

FIGS. 2 to 5 are sectional diagrams illustrating some exemplary processes for a method of forming a dielectric layer having an ONO composite structure according to some embodiments of the invention.

Referring to FIG. 2, a floating gate 118 is formed on a substrate 100, and a lower oxide layer 120 is formed on the floating gate 118.

The lower oxide layer 120 may be formed using a variety of methods. For example, an oxide may be deposited onto a top surface of the floating gate 118 by a low-pressure chemical vapor deposition (LPCVD) process to thereby form a dummy (not shown) oxide layer on the floating gate 118 to a thickness of about 30 Å to about 50 Å. Then, a wet oxidation process or a radical oxidation process may be performed on the dummy oxide layer. As another example, a radical oxidation process may be performed on a top surface of the floating gate 118 to thereby form the lower oxide layer 120. As still another example, a wet oxidation process may be performed on a top surface of the floating gate 118 to thereby form the lower oxide layer 120.

The radical oxidation process described above includes a thermal oxidation process using oxygen radicals, and the oxygen radicals are generated by dissociating oxygen from a source mixture of oxygen (O₂) gas and hydrogen (H₂) gas and a nitrogen (N₂) carrier gas at a pressure no more than about 1 Torr. Then, the durability of the lower oxide layer may be further improved by heat treating in an ambient of NO or N₂O after the lower oxide layer 120 is formed on the floating gate 118, so that an inner structure of the lower oxide layer 120 becomes more dense. In addition, a surface layer (not shown) including a molecular bond of silicon and nitrogen (hereafter referred to as a Si—N bond) is formed on a surface of the lower oxide layer 120 due to the heat treatment. The bonding energy of the Si—N bond is sufficiently strong so that hot electrons injected from the floating gate 118 do not break the Si—N bond. The heat treatment also reduces a number of thermo-electrons trapped with broken bonding sites in the lower oxide layer 120.

In detail, the substrate 100 on which the floating gate 118 is formed is loaded onto a support in an LPCVD chamber. Then, the oxide is deposited onto the top surface of the floating gate 118 to a thickness of about 30 Å to about 55 Å using a source of silane (SiH₄) gas and N₂O gas at a temperature of no less than about 750° C. and at a pressure of no more than about 1 Torr to thereby form the dummy oxide layer. Continuously, the radical oxidation process is performed to the dummy oxide layer using oxygen radicals for about one second to about five seconds in-situ with the oxide deposition process in an ambient of O₂ gas, a H₂ source gas and a N₂ carrier gas, so that the dummy oxide layer is transformed into the lower oxide layer 120.

Then, an annealing process is performed to the lower oxide layer 120 for about 15 minutes to about 25 minutes in-situ with the radical oxidation process in an ambient of a N₂O gas or a NO gas, so that the inner structure of the lower oxide layer 120 becomes dense. In these embodiments, the radical oxidation process is preferably performed at a temperature of about 750° C. to 1000° C., and is more preferably performed at a temperature of about 850° C. to 950° C. The oxygen radicals do not cause damage to the substrate 100 during the radical oxidation process since the radical oxidation process is performed only for a short time, for example, for about one second to about five seconds.

Referring to FIG. 3, a nitride layer 130 is formed on the lower oxide layer 120. In detail, the substrate 100 on which the lower oxide layer 120 is formed is loaded onto a support in an LPCVD chamber. Then, silicon nitride (Si₃N₄) is deposited onto a top surface of the lower oxide layer 120 to a thickness of about 50 Å to about 70 Å using a source gas that includes dichloro silane (Si₂H₂Cl₂) gas and ammonia (NH₃) gas at a temperature of about 780° C. and at a pressure of about 1 Torr to thereby form a silicon nitride layer as the nitride layer 130.

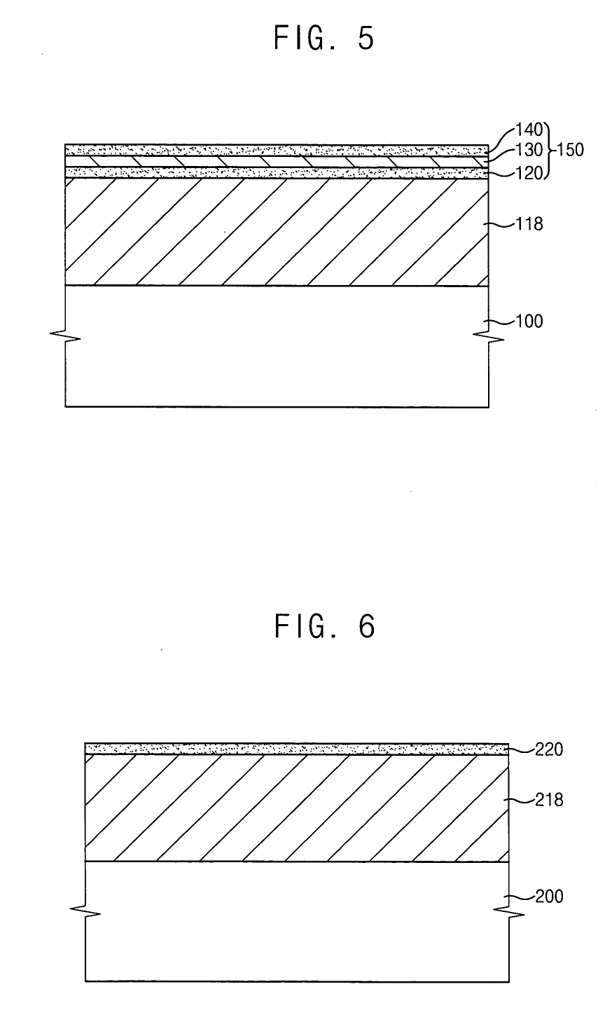

Referring to FIGS. 4 and 5, a preliminary oxide layer 138 is formed on the nitride layer 130, and the preliminary oxide layer 138 is formed into an upper oxide layer 140 by the radical oxidation process.

In detail, the substrate 100 on which the nitride layer 130 is formed is loaded onto a support in an LPCVD chamber. Then, an oxide is deposited onto the top surface of the nitride layer 130 to a thickness of about 20 Å to about 50 Å using a source that includes SiH₄ gas and N₂O gas at a temperature of no less than about 750° C. and at a pressure of no more than about 1 Torr to thereby form the preliminary oxide layer 138. Thereafter, the radical oxidation process is performed to the preliminary oxide layer 138 in-situ with the oxide deposition process in an ambient of O₂ gas, H₂ gas, and N₂ gas. The radical oxidation process includes a thermal oxidation process using oxygen radicals, and the oxygen radicals are generated by dissociating oxygen from a source mixture gas of O₂ and H₂ and a N₂ carrier gas at a pressure no more than about 1 Torr. In these embodiments, the radical oxidation process is exemplarily performed at a temperature of about 950° C. Accordingly, the preliminary oxide layer 138 is transformed into the upper oxide layer 140.

Then, to improve the durability of the upper oxide layer 140, an annealing process is performed on the upper oxide layer for about 15 minutes to about 25 minutes in-situ with the radical oxidation process in an ambient of a N₂O gas or a NO gas, so that the inner structure of the upper oxide layer 140 becomes dense. Accordingly, a dielectric layer 150 is formed into an ONO composite layer of the lower oxide layer 120, the nitride layer 130, and the upper oxide layer 140.

The upper and lower oxide layers 140 and 120 have a dense structure and a good durability, such that their thicknesses may be reduced compared with the upper and lower oxide layers of the conventional ONO composite layer. Accordingly, the thickness of the dielectric layer 150 may be reduced considerably compared to the conventional dielectric layer, and thus a reduction in the coupling coefficient of the dielectric layer 150 may be prevented. Reducing the thickness of the dielectric layer and the corresponding improvement to the coupling coefficient are in keeping with the continued industry goals of reducing the scale of semiconductor devices. Alternatively, the lower oxide layer, the nitride layer, and the upper oxide layer are formed in-situ with each other for forming the dielectric layer 150.

FIGS. 6 to 8 are sectional diagrams illustrating some exemplary processes for a method of forming a dielectric layer having an ONO composite structure according to some other embodiments of the invention. These embodiments of the invention are similar to those disclosed above with reference to FIGS. 2 to 5 except that the lower oxide layer is formed directly from the floating gate by using the radical oxidation process. Similar to the embodiments described above, an annealing process may be performed on the lower oxide layer, and thus an inner structure of the lower oxide layer becomes dense.

Referring to FIG. 6, a floating gate 218 is formed on a substrate 200, and a lower oxide layer 220 is formed on the floating gate 218.

In detail, the substrate 200 on which the floating gate 218 is formed is loaded onto a support in an LPCVD chamber. Then, a radical oxidation process is performed to an upper portion of the floating gate 218 in an ambient of an O₂ gas, H₂ gas, and a N₂ gas at a temperature of no less than about 800° C. and at a pressure of no more than about 1 Torr. In these embodiments, the radical oxidation process includes a thermal oxidation process using oxygen radicals, and the oxygen radicals are generated by dissociating oxygen from a gas mixture of O₂ and H₂ as a source and a N₂ carrier gas at a pressure of no more than about 1 Torr, and the radical oxidation process is preferably performed at a temperature of about 950° C. Accordingly, the upper portion of the floating gate 218 is transformed into the lower oxide layer 220 by the radical oxidation process. Then, an annealing process is performed to the lower oxide layer 220 for about 15 minutes to about 25 minutes in-situ with the radical oxidation process in an ambient of N₂O gas or a NO gas, so that the inner structure of the lower oxide layer 220 becomes more dense than before.

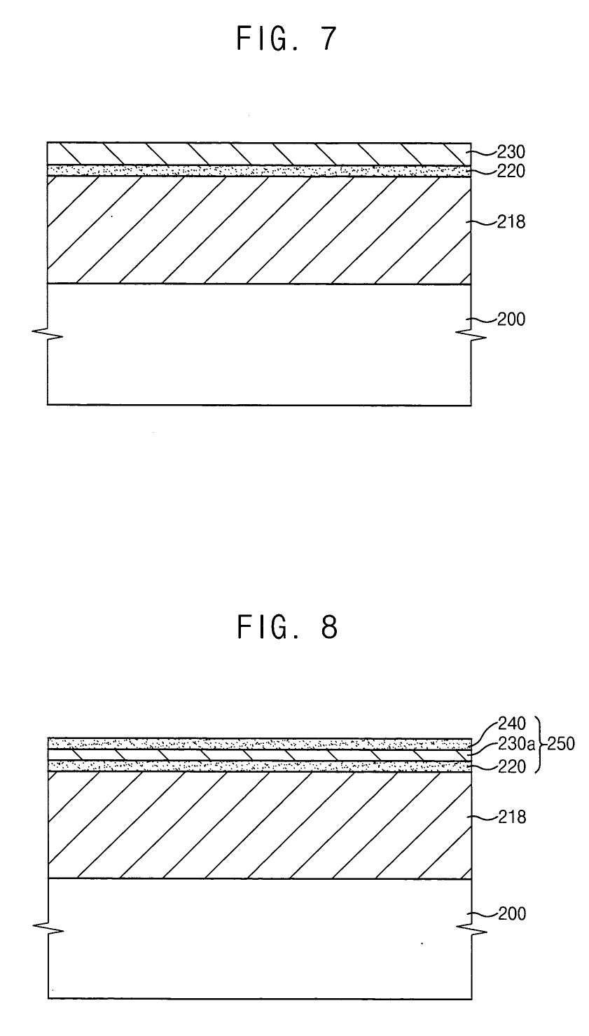

Referring to FIG. 7, a nitride layer 230 is formed on the lower oxide layer 220. IN particular, the substrate 200 on which the lower oxide layer 220 is formed is loaded onto a support in an LPCVD chamber. Then, Si₃N₄ is deposited onto a top surface of the lower oxide layer 220 to a thickness of about 100 A to about 150 A using a source gas that includes Si₂H₂Cl₂ gas and NH₃ gas at a temperature of about 780° C. and at a pressure of about 1 Torr to thereby form a silicon nitride layer as the nitride layer 230.

Referring to FIG. 8, a radical oxidation process is performed to an upper portion of the nitride layer 230, and thus the upper portion of the nitride layer 230 is transformed into an upper oxide layer 240. In detail, the substrate 200 on which the nitride layer 230 is formed is loaded onto a support in an LPCVD chamber. Then, a radical oxidation process is performed to an upper portion of the nitride layer 230 in an ambient of O₂ gas, H₂ gas, and N₂ gas at a temperature of about 950° C. and at a pressure of no more than about 1 Torr. As described above, the radical oxidation process includes a thermal oxidation process using oxygen radicals, and the oxygen radicals are generated by dissociating oxygen from a source mixture of O₂ and H₂ gas and a N₂ carrier gas at a pressure of no more than about 1 Torr. Accordingly, the upper portion of the nitride layer 230 is transformed into the upper oxide layer 240 by the radical oxidation process.

Then, an annealing process is performed on the upper oxide layer 240 for about 15 minutes to about 25 minutes in-situ with the radical oxidation process in an ambient of N₂O gas or NO gas, so that the inner structure of the lower oxide layer 220 becomes more dense and the durability of the upper oxide layer 240 is improved. Accordingly, a dielectric layer 250 according to these embodiments of the invention are formed of an ONO composite layer that includes the lower oxide layer 220, the nitride layer 230, and the upper oxide layer 240.

The upper and lower oxide layers 240 and 220 have a dense structure and a good durability, so that a thickness thereof may be reduced compared with the upper and lower oxide layers of the conventional ONO composite layer. Accordingly, a thickness of the dielectric layer 250 may be reduced considerably compared to the conventional dielectric layer. Thus, a reduction to the coupling coefficient of the dielectric layer 250 may be prevented. Reducing the thickness of the dielectric layer and the corresponding improvement to the coupling coefficient are in keeping with the continued industry goals of reducing the scale of semiconductor devices. Alternatively, the lower oxide layer, the nitride layer and the upper oxide layer are formed in-situ with each other for forming the dielectric layer 250.

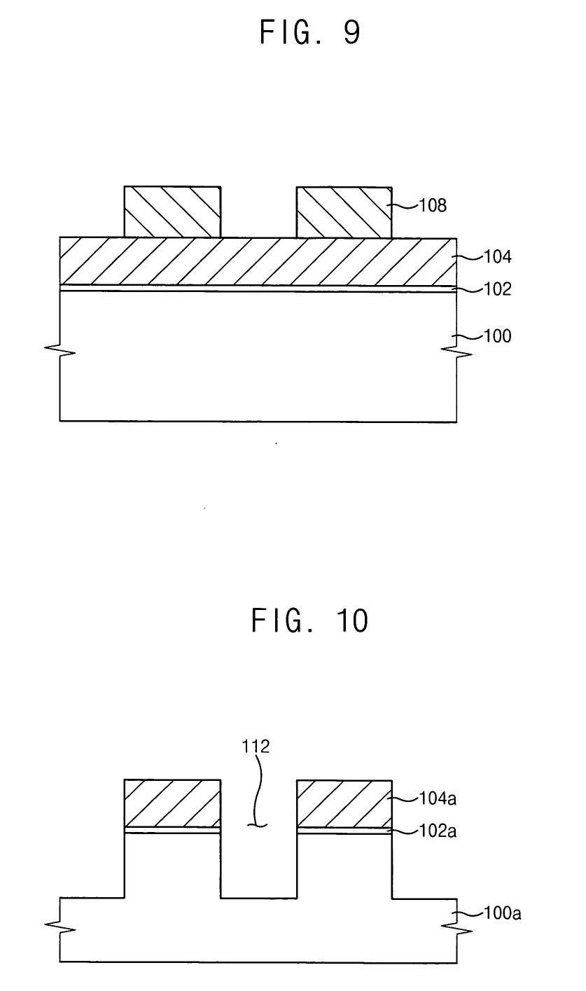

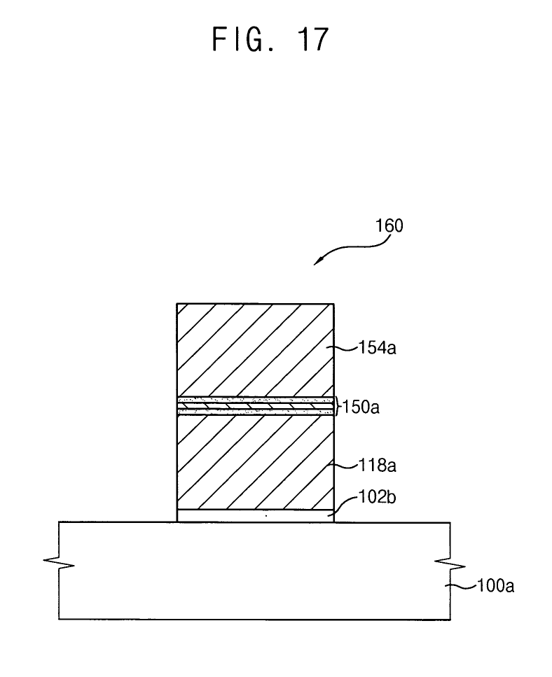

FIGS. 9 to 17 are sectional diagrams illustrating some exemplary processes for a method of manufacturing a nonvolatile memory device having a dielectric layer with an ONO composite structure according to still other embodiments of the invention. FIGS. 9 to 16 are sectional views taken along a direction substantially parallel with a bit line of the nonvolatile memory device, and FIG. 17 is a sectional view taken along a direction substantially parallel with a word line of the nonvolatile memory device.

Referring to FIG. 9, a gate oxide layer 102, a first conductive layer 104, and a hard mask 108 are sequentially formed on a substrate 100. The gate oxide layer 102 is formed on the substrate 100 to a thickness of about 60 Å. A data storing ability of the nonvolatile memory device is determined by the layer reliability of the gate oxide layer 102, and thus the gate oxide layer functions as a restriction factor to an operational ability represented as an operation cycle number of a data storing and a data erasing. A useful memory device requires at least one million operation cycles.

In view of the operation cycle, the gate oxide layer 102 is formed by a radical oxidation process using oxygen radicals at a temperature of no less than about 800° C. and at a pressure of no more than about 1 Torr in an ambient of O₂ gas, H₂ gas, and N₂ gas, so that the thickness of the gate oxide layer 102 is reduced and an inner structure of the gate oxide layer 102 becomes denser.

Then, a first conductive layer 104 is formed on the gate oxide layer 102 to a thickness of about 500 Å using an LPCVD process, and impurities are doped into the first conductive layer 104 using a conventional doping process such as a phosphorus oxychloride (POCl₃) diffusion process, an ion implantation process, or an in-situ doping process. The first conductive layer doped with impurities functions as a floating gate. In these embodiments, the first conductive layer 104 includes polysilicon or amorphous silicon.

The hard mask 108 is formed on the first conductive layer 104 to define a layout of the floating gate.

Referring to FIG. 10, trenches 112 are formed on the substrate 100 in accordance with a first conductive pattern 140a.

In detail, the substrate 100 on which the gate oxide layer 102, the first conductive layer 104, and the hard mask 108 are sequentially formed is loaded into an etching chamber. Then, the first conductive layer 104 and the gate oxide layer 102 are etched away in accordance with the hard mask 108 to thereby form a first conductive pattern 104a and a gate oxide pattern 102a. That is, portions of the first conductive layer 104 and the gate oxide layer 102, which are exposed through the hard mask 108, are etched with an etching gas that uses the hard mask as an etching mask.

Subsequently, the substrate 100 is also etched using the hard mask 108 as an etching mask to a depth of about 1200 Å to about 2500 Å to thereby form a trench 112 at an upper portion of the substrate 100. In these embodiments, the trench 112 is formed to a depth of about 1700 Å. Accordingly, an active region is formed where a conductive structure will be subsequently formed. A field region is formed by the trench 112, the field region defining the active regions that are separated from each other. The hard mask 108 is removed after completing the trench 112. Hereinafter, the substrate 100 that includes the trench 112 is designated with the reference numeral 100a.

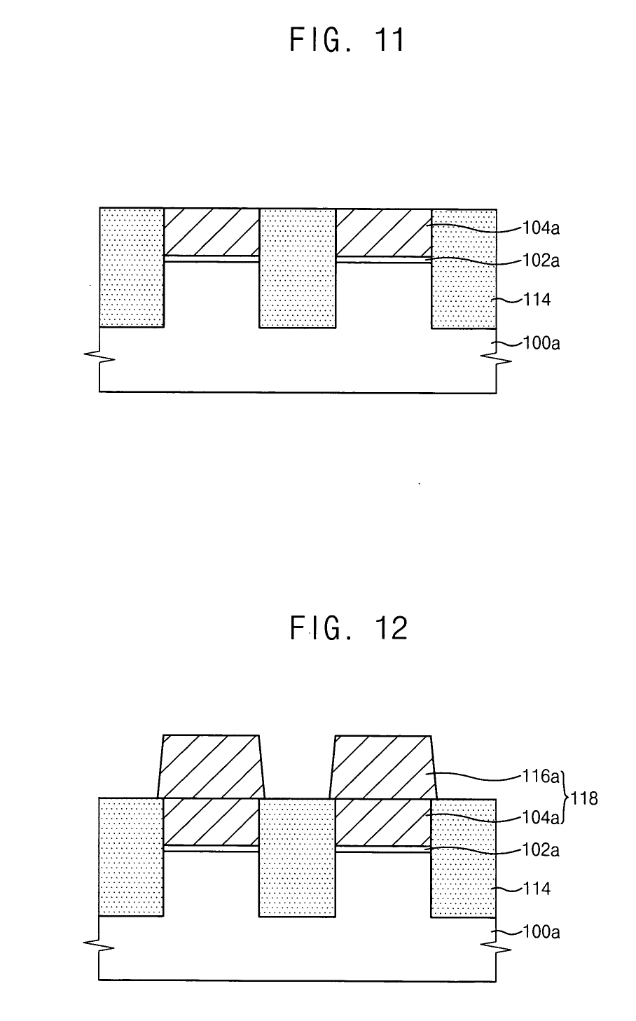

Referring to FIG. 11, an isolation layer 114 is formed in the trench 112 by an oxide deposition process and a chemical mechanical polishing (CMP) process.

In particular, an oxide having a good gap-fill characteristic may be deposited or coated onto the substrate 100a to a thickness that is sufficient to fill the trench 112, thereby forming a field oxide layer. In these embodiments, the field oxide layer is formed using a high density plasma CVD process. Then, the field oxide layer is removed and planarized by a CMP process until a top surface of the first conductive pattern 104a is exposed, so that the oxide remains in the trench 112 to thereby form a field oxide pattern 114 along the trench 112.

Referring to FIG. 12, a second conductive pattern 116a is formed on the first conductive pattern 104a, thereby completing a floating gate 118.

In particular, a second conductive layer (not shown) is formed on the substrate 100a including the field oxide pattern 114. In these embodiments, the second conductive layer is formed to a thickness of about 1200 Å by an LPCVD process. Then, impurities are doped into the second conductive layer with a conventional doping process such as a POCl₃ diffusion process, an ion implantation process, or an in-situ doping process.

An etching mask (not shown) is formed on the second conductive layer to define a layout of the floating gate 118, and the second conductive layer is partially etched using the etching mask to thereby form a second conductive pattern 116a. The etching mask is removed after completing the second conductive pattern 116a. Accordingly, the second conductive pattern 116a is stacked on the first conductive pattern 104a.

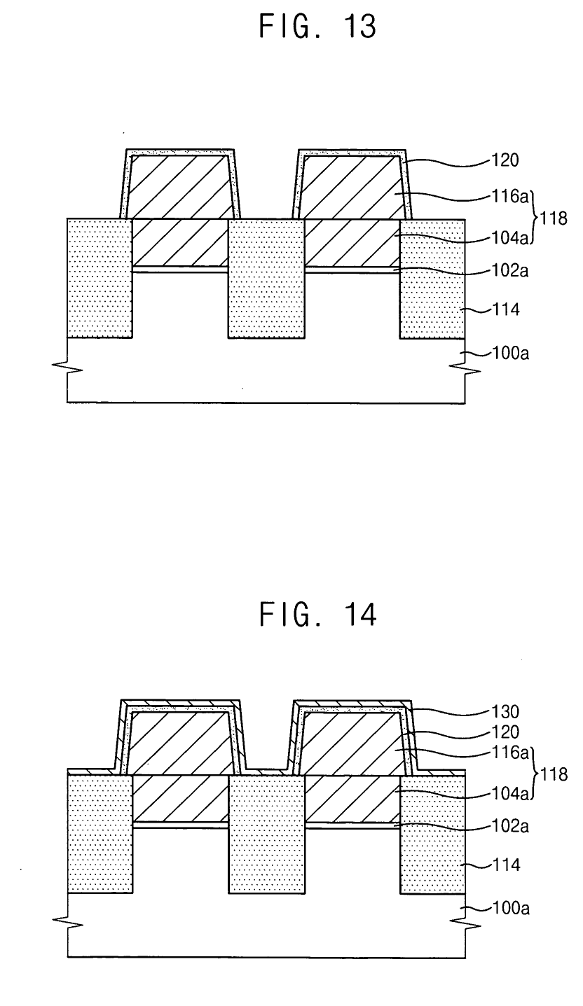

Referring to FIGS. 13 and 14, a lower oxide layer 120 and a nitride layer 130 are formed on the floating gate 118 by a radical oxidation process. In these embodiments, a top portion of the floating gate 118 is transformed into the lower oxide layer 120 by the radical oxidation process without a preliminary oxide layer, as shown in FIG. 13. An annealing process may additionally be performed on the lower oxide layer 120 in an ambient of N₂ gas. A detailed description on the lower oxide layer 120 was already disclosed for the embodiments described above, and thus an unnecessarily duplicative description is omitted to avoid redundancy.

In these embodiments, the nitride layer 130 is formed into a silicon nitride layer on the substrate 100a including the lower oxide layer 120, as shown in FIG. 14. In particular, Si₃N₄ is deposited onto a top surface of the lower oxide layer 120 and the field oxide pattern 114 using a source gas including Si₂H₂Cl₂ gas and NH₃ gas at a temperature of about 780° C. and at a pressure of no more than about 1 Torr.

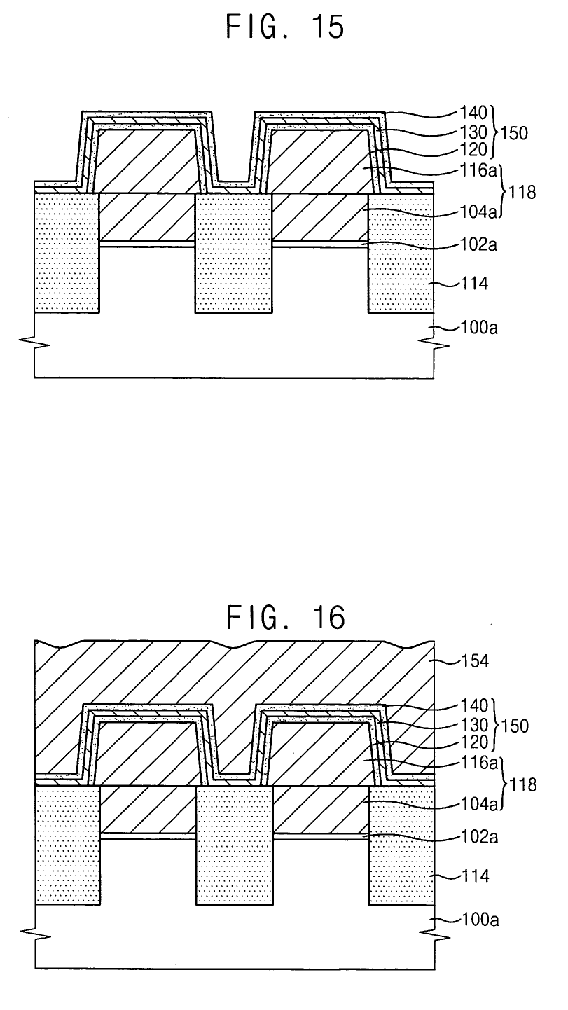

Referring to FIG. 15, a preliminary oxide layer (not shown) is formed on the nitride layer 130 and a radical oxidation process is performed on the preliminary oxide layer to thereby form an upper oxide layer 140 having a dense inner structure.

In particular, the substrate 100a on which the nitride layer 130 is formed is loaded onto a support in an LPCVD chamber. Then, an oxide is deposited onto the top surface of the nitride layer 130 to a thickness of about 20 Å to about 50 Å using a SiH₄ source gas and N₂O gas at a temperature of no less than about 750° C. and at a pressure of no more than about 1 Torr to thereby form the preliminary oxide layer. Continuously, the radical oxidation process is performed on the preliminary oxide layer in-situ with the oxygen deposition process in an ambient of O₂ gas, H₂ gas, and N₂ gas, so that the preliminary oxide layer is formed into the upper oxide layer 140. In these embodiments, the radical oxidation process includes a thermal oxidation process using oxygen radicals, and the oxygen radicals are generated by dissociating oxygen from a source mixture of O₂ gas and H₂ gas and N₂ carrier gas at a pressure no more than about 1 Torr. The radical oxidation process is performed at a temperature of about 950° C. Then, an annealing process is performed to the upper oxide layer 140 for about 15 minutes to about 25 minutes in-situ with the radical oxidation process in an ambient of N₂O gas or NO gas, so that the inner structure of the upper oxide layer 140 becomes more dense, and the durability of the upper oxide layer 140 is improved.

Accordingly, a dielectric layer 150 is formed on the floating gate 118 as an ONO composite layer of the lower oxide layer 120, the nitride layer 130, and the upper oxide layer 140.

Referring to FIG. 16, a control gate layer 154 is formed on the dielectric layer 150. In these embodiments, the control gate 154 formed into a polysilicon layer doped with N+ type impurities or a composite layer of a polysilicon layer and a metal silicide layer. Examples of the metal silicide layer include tungsten silicide (WSiₓ), titanium silicide (TiSiₓ), cobalt silicide (CoSiₓ), tantalum silicide (TaSiₓ), etc. The metal silicide layer may consist of a single layer or multiple layers, each of the layers composed of one of the silicides named above.

Referring to FIG. 17, the control gate layer 154 is patterned by a conventional photolithography process to thereby form a control gate electrode 154a. Then, the exposed dielectric layer 150 and the floating gate 118 are dry-etched away using the control gate electrode 154a as an etching mask until a top surface of the substrate 100a between the device isolation patterns is exposed to thereby form a stack type nonvolatile memory cell 160 according to a third embodiment of the present invention. That is, the stack type nonvolatile memory cell 160 includes a control gate electrode 154a, a dielectric pattern 150a, a floating gate electrode 118a and a gate oxide pattern 102b.

The nonvolatile memory cell 160 of the present invention includes a dielectric layer having improved physical properties, and thus the leakage of electrons stored in the floating gate electrode 118a is prevented.

FIGS. 18 to 23 are sectional diagrams illustrating some exemplary processes for a method of manufacturing a nonvolatile memory device having a dielectric layer with an ONO composite structure according to different embodiments of the invention. FIGS. 18 to 22 are sectional views taken along a direction substantially parallel with a bit line of the nonvolatile memory device, and FIG. 23 is a sectional view taken along a direction substantially parallel with a word line of the nonvolatile memory device.

Referring to FIG. 18, a gate oxide pattern 202a, a field oxide pattern 214 and a floating gate 218 are sequentially formed on the substrate 200 in a manner similar to that described for the embodiments illustrated in FIGS. 9-17. Since a detailed description of the gate oxide pattern 202a, the field oxide pattern 214 and the floating gate 218 was already disclosed above, another description is omitted to avoid redundancy.

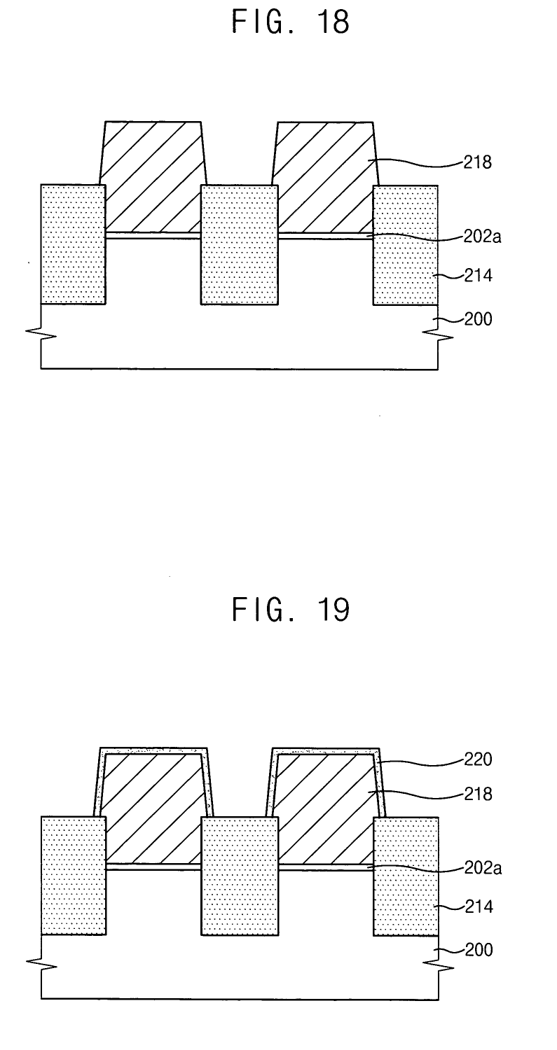

Referring to FIG. 19, a radical oxidation process using oxygen radicals is performed on a top portion of the floating gate 218, and thus the top portion of the floating gate 218 is transformed into a lower oxide layer 218. An annealing process may be further performed on the lower oxide layer 218 in an ambient of N₂ gas.

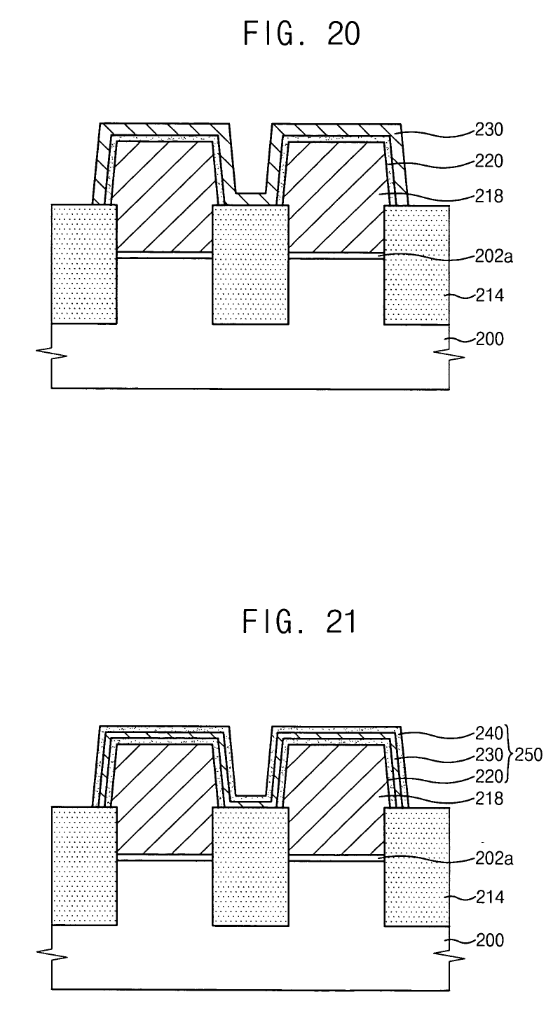

Then, as shown in FIG. 20, a nitride layer 230 is formed on the lower oxide layer 220 and the field oxide pattern 214 by an LPCVD process. A radical oxidation process using oxygen radicals is also performed on a top portion of the nitride layer 230, and thus the top portion of the nitride layer 230 is transformed into an upper oxide layer 240. Accordingly, as shown in FIG. 21, a dielectric layer 250 is formed on the floating gate 218 as an ONO composite layer consisting of the lower oxide layer 220, the nitride layer 230, and the upper oxide layer 240.

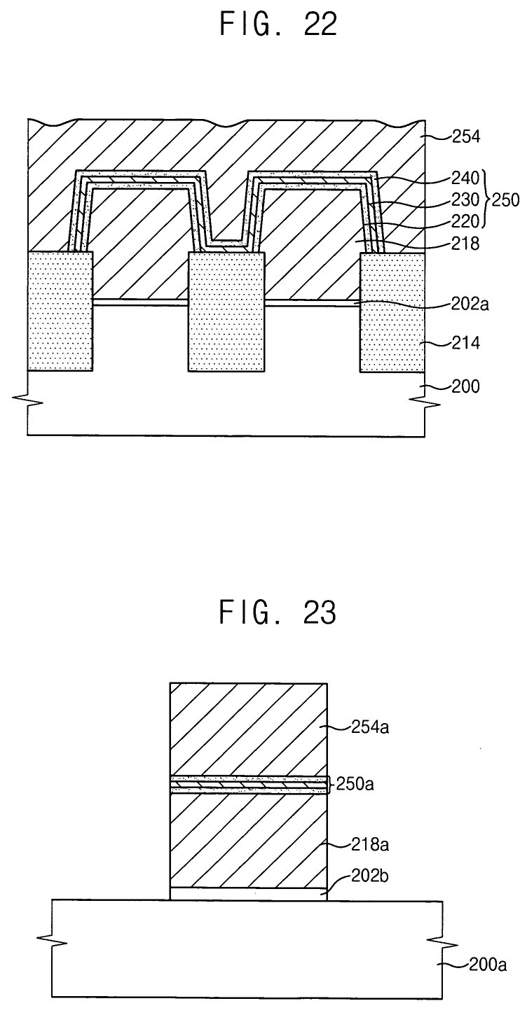

Referring to FIG. 22, a control gate layer 254 is formed on the dielectric layer 250 to a thickness of about 1200 Å. In these embodiments, the control gate 154 formed into a polysilicon layer doped with N+ type impurities or a composite layer that includes a polysilicon layer and metal silicide layer. Examples of the metal silicide layer include tungsten silicide (WSix), titanium silicide (TiSix), cobalt silicide (CoSix), tantalum silicide (TaSix), etc. The metal silicide layer may be composed of one or more of the above named materials.

Referring to FIG. 23, the control gate layer 254 is patterned by a conventional photolithography process to thereby form a control gate electrode 254a. Then, the exposed dielectric layer 250 and the floating gate 218 are dry-etched using the control gate electrode 254a as an etching mask until a top surface of the substrate 200 between the device isolation patterns is exposed to thereby form a stack type nonvolatile memory cell 260. That is, the stack type nonvolatile memory cell 260 includes a control gate electrode 254a, a dielectric pattern 250a, a floating gate electrode 218a, and a gate oxide pattern 202b.

The nonvolatile memory cell 260 includes a dielectric layer having improved physical properties, and thus the leakage of electrons stored in the floating gate electrode 118a are prevented.

According to embodiments of the invention, the physical characteristics of the dielectric layer are improved due to a dense structure and an improved durability of an oxide layer. In addition, a coupling coefficient of the dielectric layer is increased since the dielectric layer is formed to have a smaller thickness to thereby improve an insulation character of the dielectric layer. Furthermore, the electrons stored in the floating gate electrode are prevented from leaking, so that a leakage current is decreased in the nonvolatile memory cell.

The invention may be practiced in many ways. What followed are exemplary, non-limited descriptions of some embodiments of the invention.

According to some embodiments, a method of forming a dielectric layer for a semiconductor device includes forming a lower oxide layer on a substrate, and then forming a nitride layer on the lower oxide layer. A preliminary oxide layer is formed on the nitride layer, and a radical oxidation process using oxygen radicals is performed on the preliminary oxide layer to thereby form an upper oxide layer.

According to other embodiments, a method of forming a dielectric layer for a semiconductor device includes forming a lower oxide layer on a substrate, and then forming a nitride layer is formed on the lower oxide layer. An upper portion of the nitride layer is transformed into an upper oxide layer by performing a radical oxidation process on the upper portion of the nitride layer.

According to more embodiments of the invention, a method of manufacturing a nonvolatile memory device includes forming a first polysilicon layer on a substrate, and then forming a lower oxide layer on the first polysilicon layer. A nitride layer is formed on the lower oxide layer, and a preliminary oxide layer is formed on the nitride layer. A radical oxidation process using oxygen radicals is performed on the preliminary oxide layer to thereby form an upper oxide layer. A second polysilicon layer is formed on the upper oxide layer.

According to additional embodiments of the invention, a method of manufacturing a nonvolatile memory device includes forming a first polysilicon layer on a substrate, and then forming a lower oxide layer on the first polysilicon layer. A nitride layer is formed on the lower oxide layer, and a radical oxidation process is performed on an upper portion of the nitride layer to thereby transform the upper portion of the nitride layer into an upper oxide layer. A second polysilicon layer is formed on the upper oxide layer.

Although several exemplary embodiments of the invention have been described above, it is understood that the invention should not be limited to these exemplary embodiments, but that various changes and modifications may be made by one skilled in the art within the spirit and scope of the invention as defined by the attached claims.

1. A method of forming a dielectric layer for a semiconductor device, comprising:
forming a lower oxide layer on a substrate;
forming a nitride layer on the lower oxide layer;
forming a preliminary oxide layer on the nitride layer; and
performing a radical oxidation process on the preliminary oxide layer to form an upper oxide layer.

2. The method of claim 1, wherein forming the lower oxide layer includes performing a radical oxidation process to a surface of the substrate.

3. The method of claim 1, wherein forming the lower oxide layer includes:
depositing an oxide onto the substrate by a low pressure chemical vapor deposition (LPCVD) process to thereby form a dummy oxide layer; and
performing a wet oxidation process or a radical oxidation process on the dummy oxide layer.

4. The method of claim 1, further comprising heat-treating the lower oxide layer in an ambient of nitrogen monoxide (NO) or dinitrogen monoxide (N₂O).

5. The method of claim 1, further comprising heat-treating the upper oxide layer in an ambient of nitrogen monoxide (NO) or dinitrogen monoxide (N₂O).

6. The method of claim 5, wherein heat-treating the upper oxide layer is conducted in-situ with the radical oxidation process.

7. The method of claim 1, wherein performing the radical oxidation process comprises thermal oxidation using oxygen radicals, the oxygen radicals generated by dissociating oxygen from a source mixture of oxygen (O₂) gas and hydrogen (H₂) gas at a pressure no more than about one Torr.

8. The method of claim 1, wherein performing the radical oxidation process comprises performing the process at a temperature in a range between about 750° C. and about 900° C.

9. A method of forming a dielectric layer for a semiconductor device, comprising:
forming a lower oxide layer on a substrate;
forming a nitride layer on the lower oxide layer; and
transforming an upper portion of the nitride layer into an upper oxide layer by performing a radical oxidation process to the upper portion of the nitride layer.

10. The method of claim 9, wherein forming the lower oxide layer includes:
depositing an oxide onto the substrate by a low pressure chemical vapor deposition (LPCVD) process to thereby form a dummy oxide layer; and
performing a wet oxidation process or a radical oxidation process on the dummy oxide layer; and
heat-treating the dummy oxide layer in an ambient of nitrogen monoxide (NO) or dinitrogen monoxide (N₂O).

11. The method of claim 9, wherein the radical oxidation process comprises thermal oxidation using oxygen radicals, the oxygen radicals generated by dissociating oxygen from a source mixture of oxygen (O₂) gas and hydrogen (H₂) gas at a pressure of no more than about one Torr.

12. The method of claim 9, wherein forming the lower oxide layer is performed in-situ with forming the nitride layer.

13. The method of claim 9, wherein forming the nitride layer is performed in-situ with transforming the upper portion of the nitride layer.

14. The method of claim 9, wherein forming the lower oxide layer is performed in-situ with forming the nitride layer and transforming the upper portion of the nitride layer.

15. A method of manufacturing a nonvolatile memory device, the method comprising:
forming a first polysilicon layer on a substrate;
forming a lower oxide layer on the first polysilicon layer;
forming a nitride layer on the lower oxide layer;
forming a preliminary oxide layer on the nitride layer;
performing a radical oxidation process on the preliminary oxide layer to form an upper oxide layer; and
forming a second polysilicon layer on the upper oxide layer.

16. The method of claim 15, wherein forming the lower oxide layer comprises performing a radical oxidation process on a surface of the first polysilicon layer.

17. The method of claim 15, wherein forming the lower oxide layer includes:
depositing an oxide onto the first polysilicon layer by a low pressure chemical vapor deposition (LPCVD) process to thereby form a dummy oxide layer; and
performing a wet oxidation process or a radical oxidation process on the dummy oxide layer.

18. The method of claim 15, further comprising heat-treating the lower oxide layer in an ambient of nitrogen monoxide (NO) or dinitrogen monoxide (N₂O).

19. The method of claim 15, further comprising heat-treating the upper oxide layer in an ambient of nitrogen monoxide (NO) or dinitrogen monoxide (N20).

20. The method of claim 19, wherein heat treating is conducted in-situ with the radical oxidation process.

21. The method of claim 15, wherein performing the radical oxidation process comprises thermal oxidation using oxygen radicals, the oxygen radicals generated by dissociating oxygen from a source mixture of oxygen (O₂) gas and hydrogen (H₂) gas at a pressure of no more than about one torr.

22. The method of claim 15, wherein performing the radical oxidation process comprises conducting the radical operation process at a temperature in a range between about 750° C. and about 1000° C.

23. A method of manufacturing a nonvolatile memory device, the method comprising:
forming a first polysilicon layer on a substrate;
forming a lower oxide layer on the first polysilicon layer;
forming a nitride layer on the lower oxide layer;
transforming an upper portion of the nitride layer into an upper oxide layer by performing a radical oxidation process to the upper portion of the nitride layer; and
forming a second polysilicon layer on the upper oxide layer.
